(19) United States
(12) Patent Application Publication
(10) Pub. No.: US 2026/0062807 A1
(43) Pub. Date: Mar. 5, 2026

(54) GAS INJECTION AND PRE-HEATING FOR SELECTIVE GAS ACTIVATION, AND RELATED PROCESSING CHAMBERS, APPARATUS, AND METHODS

(71) Applicant: Applied Materials, Inc., Santa Clara, CA (US)

(72) Inventors: Shu-Kwan LAU, Sunnyvale, CA (US); Enle CHOO, Saratoga, CA (US); Abraham PALATY, San Jose, CA (US); Aniketnitin PATIL, San Jose, CA (US); Shantanu Rajiv GADGIL, Santa Clara, CA (US); Ala MORADIAN, Sunnyvale, CA (US); Martin Jeffrey SALINAS, San Jose, CA (US)

(21) Appl. No.: 18/950,682

(22) Filed: Nov. 18, 2024

Related U.S. Application Data
(60) Provisional application No. 63/689,517, filed on Aug. 30, 2024.

(51) Int. Cl. C23C 16/455; C23C 16/458; C30B 25/10; C30B 25/12; C30B 25/14

(52) U.S. Cl. CPC C23C 16/45561; C23C 16/4557; C23C 16/4583; C30B 25/10; C30B 25/12; C30B 25/14

(57) ABSTRACT

The present disclosure relates to gas injection and pre-heating for selective gas activation, and related chamber kits, methods, and processing chambers. In one or more embodiments, a processing chamber includes a chamber body at least partially defining an internal volume. A substrate support is disposed in the internal volume. A gas assembly is coupled to the chamber body. The gas assembly includes an injector operable to flow a gas into the internal volume. A plurality of gas lines are fluidly connected to the injector and at least one heater is operable to heat the gas.

### CROSS-REFERENCE TO RELATED APPLICATIONS

This application claims priority to U.S. Provisional Patent Application Ser. No. 63/689,517 filed on Aug. 30, 2024 the contents of which are incorporated herein by reference in their entirety.

### BACKGROUND

### Field

The present disclosure relates to gas injection and pre-heating for selective gas activation, and related chamber kits, methods, and processing chambers.

### Description of the Related Art

Semiconductor substrates are processed for a wide variety of applications, including the fabrication of integrated devices and microdevices. One method of processing substrates includes depositing a material, such as a semiconductor material or a conductive material, on an upper surface of the substrate. For example, epitaxy is one deposition process that deposit films of various materials on a surface of a substrate in a processing chamber. During processing, various parameters can affect the uniformity of material deposited on the substrate.

Operations (such as epitaxial deposition operations) involve one or more processing gases to be heated in order to be activated (such as cracked). As process gases flow in chambers the process gases (such as premixed gases) can be activated at the same temperatures, which can fail to activate certain gases and/or can degrade certain gases. As such, process recipes and adjustability windows (such as thermal adjustability) can be limited. Moreover, the process gases can be cooled by chamber component surfaces, which can hinder activation. Hence, it can be difficult to reliably pre-heat gases, such as a variety of different gases.

Therefore, a need exists for improved apparatuses and methods in semiconductor processing.

### SUMMARY

The present disclosure relates to gas injection and pre-heating for selective gas activation, and related chamber kits, methods, and processing chambers.

In one or more embodiments, a processing chamber includes a chamber body at least partially defining an internal volume. A substrate support is disposed in the internal volume. A gas assembly is coupled to the chamber body. The gas assembly includes an injector operable to flow a gas into the internal volume. A plurality of gas lines are fluidly connected to the injector and at least one heater is operable to heat the gas.

In one or more embodiments, a gas assembly includes an injector including one or more flow openings. One or more gas lines are fluidly coupled to the one or more flow openings of the injector. One or more resistive heaters are disposed within at least one of the one or more flow openings. A hatch is coupled the injector. The hatch is at least partially supporting the one or more resistive heaters. A seal is disposed about at least one of the one or more resistive heaters. One or more electrical lines are coupled to the hatch. The one or more electrical lines are electrically connected to the one or more resistive heaters.

In one or more embodiments, a method of substrate processing includes applying a power to a heater disposed along a portion of a gas flow path and flowing one or more process gases along the gas flow path into an injector of a processing chamber. The method further includes heating the one or more process gases prior to the one or more process gases flowing out of the injector and flowing the one or more process gases into a processing volume of the processing chamber.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 is a partial schematic side cross-sectional view of a processing chamber, according to one or more embodiments.

FIG. 2 is a partial schematic top view of the processing chamber including a gas supply assembly, according to one or more embodiments.

FIG. 3 is a partial schematic top view of the processing chamber including heaters in the injector, according to one or more embodiments.

FIG. 4 is a partial schematic enlarged side cross-sectional view of the processing chamber with the heaters around the gas lines and one or more insulation sleeves disposed in the injector shown in FIG. 2, according to one or more embodiments.

FIG. 5 is a partial schematic enlarged side cross-sectional view of the processing chamber with the heaters in the flow openings of the injector shown in FIG. 3, and a vacuum seal, according to one or more embodiments.

FIG. 6 is a schematic block diagram view of a method of substrate processing, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure relates to gas injection and pre-heating for selective gas activation, and related chamber kits, methods, and processing chambers. In one or more embodiments, gases (such as two or more gas groups) can be separately injected into a processing volume of a processing chamber. In one or more embodiments, the gases can be independently pre-heated. A variety of pre-heating apparatus can be used, such as a gas line heater jacket and/or an in-line resistive heater. In one or more embodiments, an insulation sleeve is disposed in an injector (such as an inject ring) to facilitate reduced cooling of the process gases.

The disclosure contemplates that terms such as “couples,” “coupling,” “couple,” and “coupled” may include but are not limited to embedding, bonding, welding, fusing, melting together, interference fitting, and/or fastening such as by using bolts, threaded connections, pins, and/or screws. The disclosure contemplates that terms such as “couples,” “coupling,” “couple,” and “coupled” may include but are not limited to integrally forming. The disclosure contemplates that terms such as “couples,” “coupling,” “couple,” and “coupled” may include but are not limited to direct coupling and/or indirect coupling, such as indirect coupling through components such as links, blocks, and/or frames.

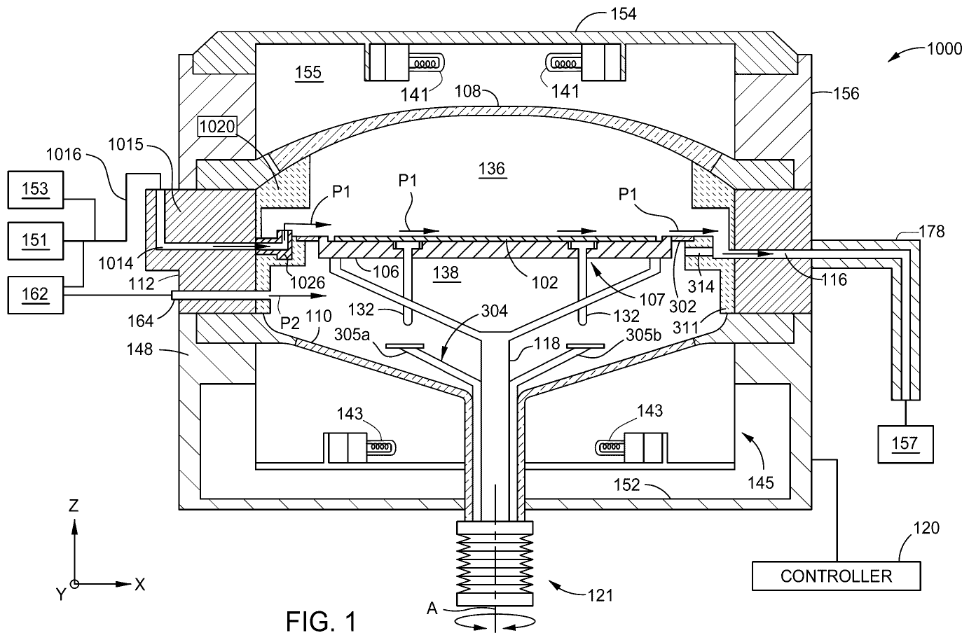

FIG. 1 is a partial schematic side cross-sectional view of a processing chamber 1000, according to one or more embodiments. The processing chamber 1000 is a deposition chamber. In one or more embodiments, the processing chamber 1000 is an epitaxial deposition chamber. In one or more embodiments, the processing chamber 1000 is utilized to grow an epitaxial film on a substrate 102. The processing chamber 1000 creates a cross-flow of precursors across a top surface of the substrate 102. The processing chamber 1000 is shown in a processing condition in FIG. 1.

The processing chamber 1000 includes an upper body 156, a lower body 148 disposed below the upper body 156, and a flow module 112 disposed between the upper body 156 and the lower body 148. The upper body 156, the flow module 112, and the lower body 148 form a chamber body. An injector 1015 (e.g., an inject ring) is disposed in between the flow module 112 and the upper body 156. Disposed within the chamber body is a substrate support 106, an upper plate 108 (such as an upper window and/or an upper dome), a lower plate 110 (such as a lower window and/or a lower dome), a plurality of upper heat sources 141, and a plurality of lower heat sources 143. As shown, a controller 120 is in communication with the processing chamber 1000 and is used to control processes and methods, such as the operations of the methods described herein. The present disclosure contemplates that each of the heat sources described herein can include one or more of: lamp(s), resistive heater(s), light emitting diode(s) (LEDs), and/or laser(s). The present disclosure contemplates that other heat sources can be used. The present disclosure contemplates that the upper plate 108 and/or the lower plate 110 can be in the shape of a dome or can be in another shape, such as flat, concave, or another contour.

The substrate support 106 is disposed between the upper plate 108 and the lower plate 110. The substrate support 106 includes a support face that supports the substrate 102. The plurality of upper heat sources 141 are disposed between the upper window and a lid 154. The plurality of upper heat sources 141 form a portion of the upper heat source module 155. The lid 154 may include a plurality of sensors disposed therein or thereon for measuring the temperature within the processing chamber 1000. The plurality of lower heat sources 143 are disposed between the lower plate 110 and a floor 152. The plurality of lower heat sources 143 form a portion of a lower heat source module 145. In one or more embodiments, the upper plate 108 is an upper dome and is formed of an energy transmissive material, such as quartz. In one or more embodiments, the lower plate 110 is a lower dome and is formed of an energy transmissive material, such as quartz. A pre-heat ring 302 is disposed outwardly of the substrate support 106. A stop 304 includes a plurality of arms 305a, 305b that each include a lift pin stop on which at least one of the lift pins 132 can rest when the substrate support 106 is lowered (e.g., lowered from a process position to a transfer position).

The internal volume has the substrate support 106 disposed therein. The substrate support 106 includes a top surface on which the substrate 102 is disposed. The substrate support 106 is attached to a shaft 118. The shaft 118 is connected to a motion assembly 121. The motion assembly 121 includes one or more actuators and/or adjustment devices that provide movement and/or adjustment for the shaft 118 and/or the substrate support 106.

The substrate support 106 may include lift pin perforations 107 disposed therein. The lift pin perforations 107 are sized to accommodate a lift pin 132 for lifting of the substrate 102 from the substrate support 106 either before or after a deposition process is performed.

The chamber body includes a first liner 1020 and a second liner 311. The second liner 311 is disposed below the first liner 1020. The pre-heat ring 302 is supported on a ledge of the second liner 311

The injector 1015 (which can define at least part of one or more sidewalls of the processing chamber 1000) includes one or more flow openings 1014 in fluid communication with the processing volume 136 of the internal volume. The one or more flow openings 1014 are in fluid communication with one or more flow inlets (such as one or more flow gaps between the first liner 1020 and the second liner 311). One or more inject blocks 1026 having one or more flow openings formed therein can be disposed in the one or more flow openings. The injector 1015 is fluidly connected to one or more process gas sources 151 and one or more cleaning gas sources 153. One or more gas lines 1016 extend between the one or more process gas sources 151 and/or one or more cleaning gas sources 153 and the injector. The purge gas inlet(s) 164 are fluidly connected to one or more purge gas sources 162. The one or more gas exhaust outlets 116 are fluidly connected to an exhaust pump 157. One or more process gases supplied using the one or more process gas sources 151 can include one or more reactive gases (such as one or more of silicon-containing, phosphorus-containing, and/or germanium-containing gases, and/or one or more carrier gases (such as one or more of nitrogen (N2) and/or hydrogen (H2)), and/or one or more etchant gases (such as one or more of hydrogen and/or chlorine (such as hydrochloric acid (HCl)). One or more purge gases supplied using the one or more purge gas sources 162 can include one or more inert gases (such as one or more of argon (Ar), helium (He), and/or nitrogen (N2)). One or more cleaning gases and/or etching gases supplied using the one or more cleaning gas sources 153 can include one or more of hydrogen and/or chlorine (such as hydrochloric acid (HCl)). In one or more embodiments, the one or more process gases include silicon hydrides (such as one or more silanes and/or one or more chlorinated silanes), germanium (such as germane (GeH4)), boron (such as diborane (B2H6)), and/or phospine (PH3).

The one or more gas exhaust outlets 116 are further connected to or include an exhaust system 178. The exhaust system 178 fluidly connects the one or more gas exhaust outlets 116 and the exhaust pump 157. The exhaust system 178 can assist in the controlled deposition of a layer on the substrate 102. The exhaust system 178 is disposed on an opposite side of the processing chamber 1000 relative to the flow module 112.

During a deposition operation (e.g., an epitaxial growth operation), the one or more process gases P1 flow through the injector 1015 and into the processing volume 136 to flow horizontally over the substrate support 106 and the substrate 102 and to the one or more gas exhaust outlets 116. The one or more purge gases P2 are supplied from one or more purge gas sources 162 to the purge volume 138 through one or more purge gas inlets 164. The one or more purge gases P2 flow simultaneously with the flowing of the one or more process gases P1. The one or more process gases P1 are exhausted through exhaust gaps between the first liner 1020 and the second liner 311, and through the one or more gas exhaust outlets 116. The one or more purge gases P2 are exhausted through the same exhaust gaps between the first liner 1020 and the second liner 311 or through exhaust opening(s) 314, and through the same one or more gas exhaust outlets 116 as the one or more process gases P1. The present disclosure contemplates that that one or more purge gases P2 can be separately exhausted through one or more second gas exhaust outlets that are separate from the one or more gas exhaust outlets 116.

The injector 1015 can be formed of a transparent material, such as a clear quartz, to allow the electromagnetic radiation to pass therethrough. Other materials, such as opaque materials, are contemplated as well. For example, the injector 1015 can be formed of an opaque material configured to absorb electromagnetic radiation to activate gases. The opaque material has an emissivity that is greater than or equal to 0.45 at 1,000 degrees Celsius. In one or more embodiments, the emissivity of the opaque material is within a range of 0.45 to 0.9, or higher, at 1,000 degrees Celsius. In one or more embodiments, the emissivity is within a range of 0.45 to 0.85, such as about 0.80. The opaque material has a thermal conductivity that is less than 10.0 W/m-K at a processing temperature. In one or more embodiments, the thermal conductivity of the opaque material is less than 5.0 W/m-K, such as less than 3.0 W/m-K. In one or more embodiments, the thermal conductivity of the opaque material is about 1.5. The opaque material includes silicon carbide (SiC), graphite coated with SiC, and/or opaque quartz (such as black quartz, grey quartz, and/or white quartz). In one or more embodiments, the opaque material is formed of SiC. In one or more embodiments, the SiC is pure SiC (e.g., having an atomic percentage of at least 99% for silicon and carbon) formed using chemical vapor deposition (CVD). It is believed that the pure SiC is resistant to process gases (e.g., corrosion resistant) and facilitates high absorption and emissivity. Other materials are contemplated for the injector 1015. For example, metal(s) (such as stainless steel and/or aluminum) and/or ceramic(s) can be used for the injector 1015.

The injector 1015 can include one or more heaters configured to heat the one or more processing gases P1. In one or more embodiments, the one or more heaters are disposed within the one or more flow openings 1014 disposed in the injector 1015. In one or more embodiments, the one or more heaters are disposed outside the one or more flow openings 1014 of the injector 1015. In one or more embodiments, the heaters are disposed around the one or more gas lines 1016. The one or more heaters include resistive heaters.

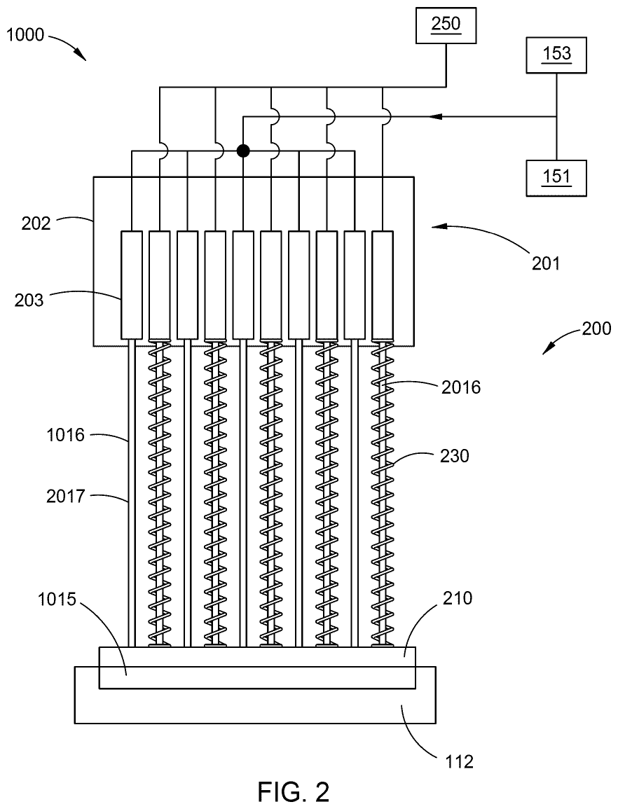

FIG. 2 is a partial schematic top view of the processing chamber 1000 including a gas supply assembly 200, according to one or more embodiments.

The gas supply assembly 200 is disposed between the one or more process gas sources 151 and/or the one or more cleaning gas sources 153 and the injector 1015 of the processing chamber 1000. During a processing operation, the one or more process gases P1 flow from the one or more process gas sources 151 to the gas supply assembly 200. The one or more process gases P1 then flow from the gas supply assembly 200 to the injector 1015 and into the processing volume as described in FIG. 1. In one or more embodiments, the gas supply assembly 200 includes a gas manifold 201. The gas manifold includes a body 202 and one or more gas channels 203. The gas channels 203 are disposed within the body 202. The gas channels 203 are fluidly connected to the one or more process gas sources 151 and the one or more cleaning gas sources 153. In one or more embodiments, the flow of the one or more process gases P1 to each gas channel 203 is individually controllable so that the one or more process gases P1 flow into some gas channels 203 and not into other gas channels 203. In one or more embodiments, the flow rate of the one or more processing gases P1 into each gas channel 203 can be controlled. In one or more embodiments, the gas channels 203 respectively are part of a flow controller (such as a valve, for example a mass flow controller (MFC)).

The gas supply assembly 200 includes gas lines 1016 extending between the gas manifold 201 and an inject cap 210 coupled to the injector 1015. The gas lines 1016 are fluidly connected to the one or more gas channels 203. In one or more embodiments, the gas lines 1016 include heated gas lines 2016 and thermally passive (e.g., non-actively heated) gas lines 2017. The present disclosure contemplates that a first gas composition can be flowed to the heated gas lines 2016 and a second gas composition (which is different than the first gas composition) can be flowed to the thermally passive gas lines 2017. The heated gas lines 2016 include one or more heaters 230 disposed around each gas line 1016. In one or more embodiments, each heater 230 is a resistive heater connected to a power source 250. During a heating operation the power source 250 supplies an electric current to the heaters 230. When the current is applied to the heaters 230, the heaters 230 increase in temperature. In one or more embodiments, the heaters 230 are wires, coils, rods, or a combination thereof. The heaters 230 respectively can be part of jackets disposed around the respective heated gas lines 2016. The heated gas lines 2016 and thermally passive gas lines 2017 can be disposed in an alternating arrangement with respect to each other. In one or more embodiments, all of the gas lines 1016 are heated gas lines 2016. In one or more embodiments, all the gas lines are thermally passive gas lines 2017. In one or more embodiments, each heated gas line 2016 is individually controllable from one another so that some heated gas lines 2016 can be activated while other heated gas lines 2016 are not activated or are activated to heat to a different temperature. The present disclosure contemplates that the heaters 230 of the heated gas lines 2016 are individually controllable such that respective heaters 230 are heated to different temperatures for different activation temperatures. The present disclosure also contemplates that different gas compositions are flowed to respective heated gas lines 2016.

During a processing operation, the one or more processing gases P1 flow from the one or more process gas sources 151 to the gas manifold 201. The process gases P1 proceed to flow into the one or more gas channels 203 of the gas manifold 201. The process gases P1 then proceed to flow through some or all of the gas lines 1016. In one or more embodiments, the heaters 230 in the heated gas lines 2016 are activated in order to increase the temperature of the one or more process gases P1 as they flow though the heated gas lines 2016. The temperature of the one or more process gases P1 flowing through the heated gas lines 2016 is increased to an activation temperature. The present disclosure contemplates that the activation temperatures for the gases can depend on parameters (such as gas composition and gas flow rate, for example. The activation temperature causes the one or more process gases P1 to become activated. In one or more embodiments, when the one or more process gases P1 are activated, one or more precursor materials within the one or more process gases P1 are cracked for deposition over the substrate 102 as the one or more process gases P1 flow over the substrate 102. After the one or more process gases P1 are heated, the one or more process gases P1 flow from the one or more gas lines 1016, into the injector 1015, and over the substrate 102.

In one or more embodiments, the one or more process gases P1 that flow through the heated gas lines 2016 are not heated using the heaters 230 and the one or more process gases that flow the thermally passive gas lines 2017 are not heated using the heaters 230. In one or more embodiments, each gas line 1016 is a heated gas line 2016 that can be individually controlled. Therefore, a controller could determine which of the one or more process gases P1 are activated so that a subset of precursor materials are deposited. The present disclosure contemplates that a gas flowing through the thermally passive gas lines 2017 is activated by the heat sources 141, 143 without the use of the heaters 230.

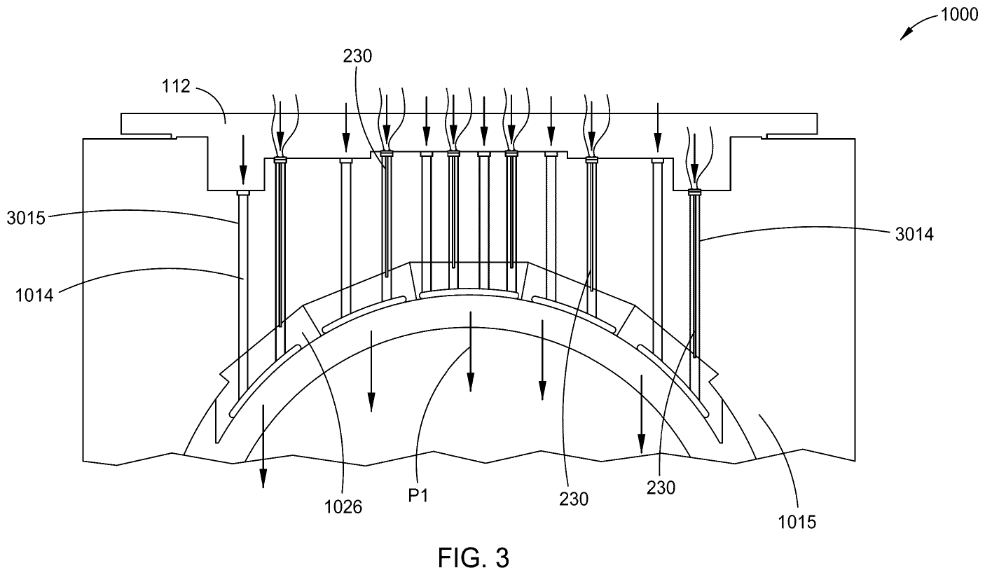

FIG. 3 is a partial schematic top view of the processing chamber 1000 including heaters 230 in the injector 1015, according to one or more embodiments.

The heaters 230 are disposed in one or more flow openings 1014 of the injector 1015 through which the one or more process gases P1 flow. The heaters 230 can be formed of silicon carbide (SiC), a metallic material, and/or a ceramic material. Other materials are contemplated for the heaters 230. The heaters 230 can be disposed about the respective flow openings 1014. In one or more embodiments, the flow openings 1014 include heated flow openings 3014 and thermally passive (e.g., non-actively heated) flow openings 3015. The heated flow openings 3014 include one or more heaters 230 disposed within and/or around each flow opening 1014. During a heating operation the power source 250 supplies an electric current to the heaters 230. When the current is applied to the heaters 230, the heaters 230 increase in temperature, such as due to a voltage applied across the heaters 230. The heated flow openings 3014 and thermally passive flow openings 3015 can be disposed in an alternating arrangement with respect to each other. In one or more embodiments, all of the flow openings 1014 are heated flow openings 3014. In one or more embodiments, all the flow openings 1014 are thermally passive flow openings 3015. In one or more embodiments, each heated gas line 2016 is individually controllable from one another so that some heated flow openings 3014 can be activated while other heated flow openings 3014 are not activated or are activated to heat to a different temperature.

During a processing operation, the one or more processing gases P1 flow from the one or more process gas sources 151 to the injector 1015. The process gases P1 proceed to flow into the one or more flow openings 1014 of the injector. The process gases P1 then proceed to flow through some or all of the flow openings 1014. In one or more embodiments, the heaters 230 in the heated flow openings 3014 are activated in order to increase the temperature of the one or more process gases P1 as they flow though the heated flow openings 3014. The temperature of the one or more process gases P1 flowing through the heated flow openings 3014 is increased to an activation temperature. After the one or more process gases P1 are heated, the one or more process gases P1 flow from the one or more flow openings 1014 into the inject blocks 1026 and over the substrate 102.

In one or more embodiments, the one or more process gases P1 that flow through the heated flow openings 3014 are not activated and the one or more process gases that flow the thermally passive flow openings 3015 are not activated. In one or more embodiments, each flow opening 1014 is a flow opening line that can be individually controlled. Therefore, a controller could determine which of the one or more process gases P1 are activated so that a subset of precursor materials are deposited. In one or more embodiments, the flow of the one or more process gases P1 to each flow opening 1014 is individually controllable so that the one or more process gases P1 flow into some flow openings 1014 and not into other flow openings 1014. In one or more embodiments, the flow rate of the one or more processing gases P1 into each flow opening 1014 can be controlled.

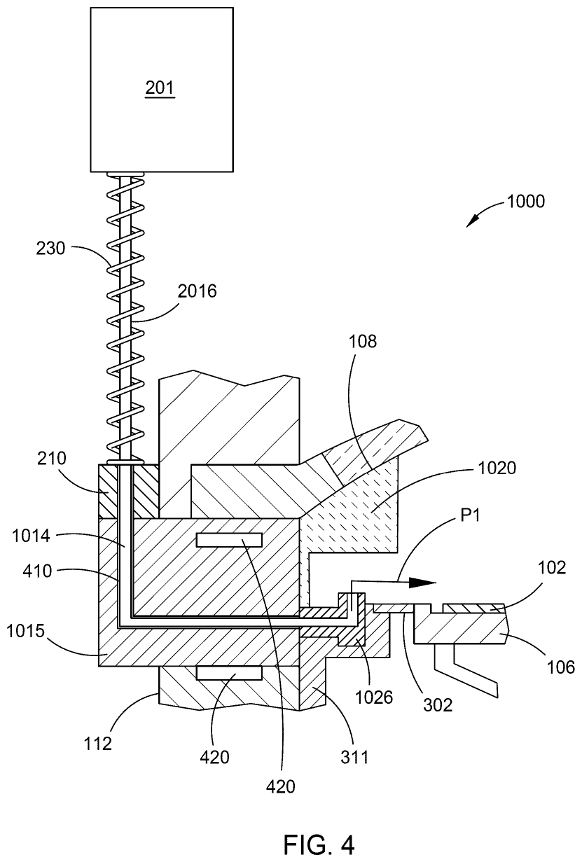

FIG. 4 is a partial schematic enlarged side cross-sectional view of the processing chamber 1000 including the gas supply assembly 200 shown in FIG. 2, according to one or more embodiments.

In one or more embodiments, the injector 1015 includes one or more cooling channels 420. The one or more cooling channels 420 are configured to flow a cooling fluid through the injector 1015. The cooling fluid is a fluid having a high thermal conductivity such as water. The cooling channels 420 prevent the injector 1015 from increasing in temperature during a heating operation. As the one or more process gases P1 flow through the injector 1015, the temperature of the injector 1015 increases. As the temperature of the injector 1015 increases, the injector 1015 can expand and deform. The one or more cooling channels 420 help maintain the temperature of the injector 1015 so that the injector 1015 is prevented from deforming.

The injector 1015 includes an insulator 410 (such as an insulator sleeve or an insulator coating). In one or more embodiments, the insulator 410 is disposed within one or more flow openings 1014, around the one or more flow openings 1014, or a combination thereof. The insulator 410 is formed of a material having a low thermal conductivity, such as quartz. The insulator 410 prevents the one or more process gases P1 from cooling as the one or more process gases flow through the one or more flow openings 1014 of the injector 1015. For example, the insulator 410 facilitates the one or more process gases P1 retaining the pre-heating from the heater(s) 230.

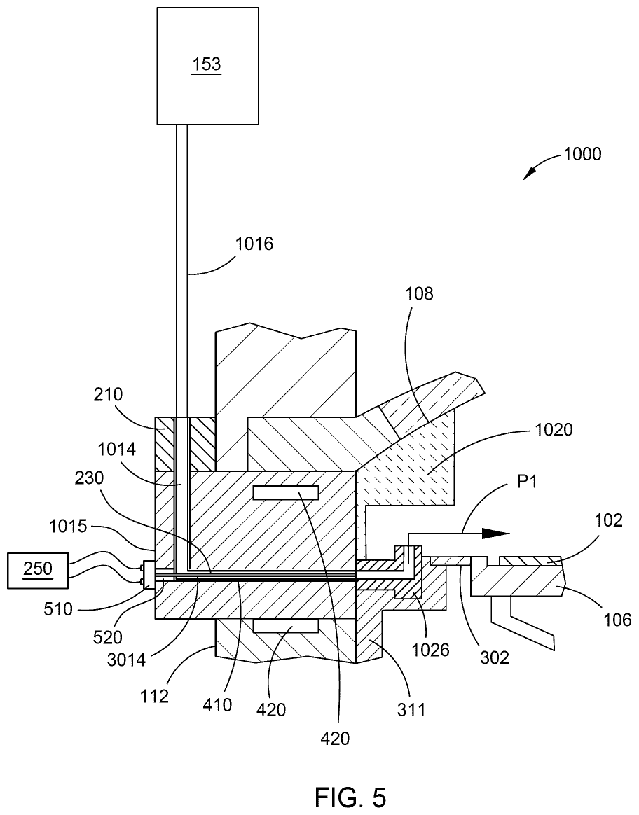

FIG. 5 is a partial schematic enlarged side cross-sectional view of the processing chamber 1000 with the heaters 230 in the flow openings 1014 of the injector 1015 shown in FIG. 3, according to one or more embodiments.

The injector 1015 includes a hatch 510 and a seal 520. In one or more embodiments, the seal 520 is a vacuum seal. The hatch 510 can be opened so that a heater 230 can be inserted into a flow opening 1014 of the one or more flow openings 1014 of the injector 1015. After the heater is inserted into the one or more flow openings 1014, the hatch 510 is shut. When the processing chamber 1000 is under pressure (such as vacuum pressure), the seal 520 prevents any air from entering the one or more flow openings 1014 through the hatch 510 and/or prevents process gases from flowing out of the flow openings 1014 and into atmosphere. In one or more embodiments, the power source 250 is electrically coupled to the heater 230 through the hatch 510 using a plurality of electrical lines (such as wires) coupled to the hatch 510. A common hatch 510 can be used across the flow openings 1014, or a plurality of hatches 510 can be used that correspond to a plurality of flow openings 1014. An insulator 410 is disposed about the respective heaters 230. In one or more embodiments, the insulator 410 is a quartz sleeve having a lower thermal conductivity than the injector 1015. The seal 520 is disposed about at least one heater 230 in a retention opening that extends between the flow opening(s) 1014 and an outer surface of the injector 1015. The heater(s) 230 are at least partially supported by the hatch 510. The heater(s) 230 can be coupled to the hatch 510 such that the heater(s) 230 are pulled from the flow opening(s) 1014 as the hatch 510 is pulled away from the injector 1015. The seal 520 can abut against the hatch 510. At least part of the injector 1015 can separate the heater(s) 230 from the one or more cooling channels 420.

During a processing operation, the one or more process gases P1 flow from the one or more process gas sources 151 into the one or more flow openings 1014 of the injector 1015. The one or more process gases P1 continue to flow through the one or more flow openings 1014 and about the heater 230. As the one or more process gases flow about the heater 230 the one or more process gases come into contact with the heater 230 which increases the temperature of the one or more process gases P1. The insulator 410 facilitates preventing the one or more process gases P1 from being cooled by the one or more cooling channels 420. The one or more process gases P1 continue to flow through the one or more flow openings 1014 and into the process volume 136.

In one or more embodiments, during a maintenance operation, the heaters 230 deposited inside the one or more flow openings 1014 are removed. The deposition process can cause the unwanted deposition of material on the heaters 230 and the insulator 410. During the maintenance operation, the hatch 510 is opened and the heaters 230 are removed for cleaning and/or replacement. In one or more embodiments, the insulator 410 can be removed for cleaning and/or replacement as well.

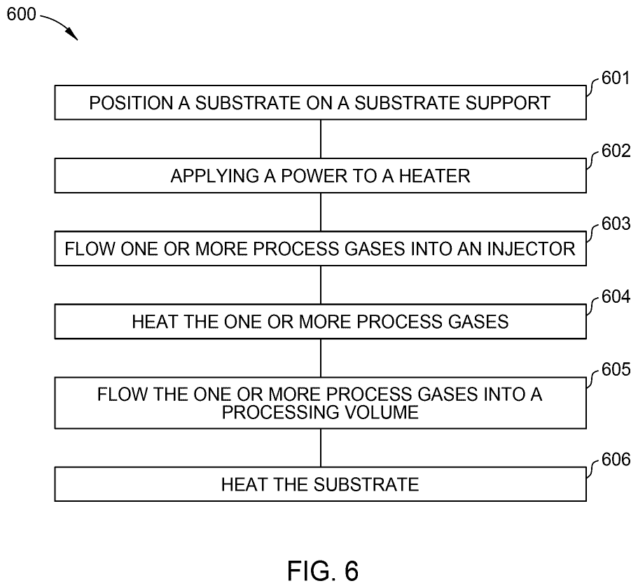

FIG. 6 is a schematic block diagram view of a method 600 of substrate processing, according to one or more embodiments. In one or more embodiments, the method 600 is performed using one or more components of the processing chamber 1000 described herein.

Optional operation 601 of method 600 includes positioning a substrate on a substrate support in a processing volume of a processing chamber. In one or more embodiments, the positioning includes moving a substrate support and/or a plurality of lift pins relative to each other to land the substrate on the substrate support.

Operation 602 of the method 600 includes applying a power to a heater. In one or more embodiments, the heater is disposed along a portion of a gas flow path. In one or more embodiments, the heater is a resistive heater. When the current is applied to the heater, the heater increases in temperature. In one or more embodiments, the heater is a wire, a coil, a rod, or a combination thereof. In one or more embodiments, the heater 230 is disposed around (e.g., wound around) one or more gas lines 1016 to form a heated gas line 2016. In one or more embodiments, the heater 230 is disposed inside and/or around a flow opening 1014 of the injector 1015 to form a heated flow opening 3014.

Operation 603 of the method 600 includes flowing one or more process gases from one or more process gas sources. In one or more embodiments, the one or more process gases are flowed along the gas flow path. The one or more process gases can include one or more reactive gases (such as one or more of silicon-containing, phosphorus-containing, and/or germanium-containing gases, one or more carrier gases (such as one or more of nitrogen (N2) and/or hydrogen (H2)), and/or one or more etchant gases (such as one or more of hydrogen and/or chlorine (such as hydrochloric acid (HCl)). In one or more embodiments, the one or more process gases include a first gas composition flowed to a subset of gas lines and/or flow openings, and a second gas composition flowed to second subset of gas lines and/or flow openings.

Operation 604 of the method 600 includes heating the one or more process gases of operation 603. The one or more process gases are heated by flowing the one or more process gases through the one or more heated gas lines 2016 and/or the one more heated flow openings 3014. The one or more process gases are heated to a second temperature higher than the first temperature. In one or more embodiments, a portion of the one or more process gases is heated and a portion of the one or more process gases is not heated. The one or more process gases are heated by the heaters prior to flowing out of the injector 1015 and into the processing volume.

Operation 605 of the method 600 includes flowing the one or more process gases over the substrate. The one or more process gases flow from the injector into processing volume. The one or more process gases flow across the substrate while within the processing volume. In one or more embodiments, a portion of the one or more process gases that was heated in operation 604 deposits a layer of a deposition material over the substrate.

Operation 606 includes heating the substrate to a substrate temperature. In one or more embodiments, the substrate temperature is less than 550 degrees Celsius, such as less than 500 degrees Celsius. In one or more embodiments, the substrate temperature is 450 degrees Celsius or less, such as 400 degrees Celsius or less, for example 350 degrees Celsius or less. In one or more embodiments, the substrate temperature is within a range of 100 degrees Celsius to 500 degrees Celsius, such as 200 degrees Celsius to 500 degrees Celsius. Other temperatures are contemplated.

Benefits of the present disclosure include activation of one or more process gases, activation of a variety of process gases, reduced or eliminated cooling and/or depletion of process gases, and thermal adjustability. Benefits also include increased growth rates, increased deposition efficiency, and decreased maintenance and decreased cost. Benefits further include adjustability of activation for process adjustability, such as based on varying gas compositions and/or gas flow rates, and enlarged adjustability windows (such as for substrate temperature, gas velocity, and gas partial pressure). As an example, a process recipe used to form SiGeB layers can include GeH₄ gas and B₂H₆ gas, which can involve lower activation energy than dichlorosilane (DCS). In one or more embodiments, GeH₄ gas and B₂H₆ gas can be injected together through one or more non-actively heated paths, and DCS can be injected separately through one or more actively heated paths.

It is contemplated that one or more aspects disclosed herein may be combined. As an example, one or more aspects, features, components, operations and/or properties of the processing chamber 1000, the injector 1015, the flow openings 1014, the inject blocks 1026, the heaters 230, the heated gas lines 2016, thermally passive gas lines 2017, heated flow openings 3014, thermally passive flow openings 3015, the insulator 410, the cooling channels 420, the hatch 510, the seal 520, and/or the method 600 may be combined. Moreover, it is contemplated that one or more aspects disclosed herein may include some or all of the aforementioned benefits.

While the foregoing is directed to embodiments of the present disclosure, other and further embodiments of the disclosure may be devised without departing from the basic scope thereof, and the scope thereof is determined by the claims that follow.

What is claimed is:

1. A processing chamber, comprising:
a chamber body at least partially defining an internal volume;
a substrate support disposed in the internal volume; and
a gas assembly coupled to the chamber body, the gas assembly comprising:
an injector operable to flow a gas into the internal volume,
a plurality of gas lines fluidly connected to the injector, and
at least one heater operable to heat the gas.

2. The processing chamber of claim 1, wherein the at least one heater comprises a coil disposed about at least one of the plurality of gas lines.

3. The processing chamber of claim 1, wherein the at least one heater comprises a heater rod disposed in at least one flow opening of the injector such that the gas flows about the heater rod.

4. The processing chamber of claim 1, wherein the at least one heater is a resistive heater.

5. The processing chamber of claim 1, wherein at least one heater comprises one or more of silicon carbide, a metallic material, or a ceramic material.

6. The processing chamber of claim 1, wherein the plurality of gas lines comprise heated gas lines and thermally passive gas lines disposed in an alternating arrangement with respect to each other.

7. The processing chamber of claim 1, wherein the injector comprises one or more cooling channels, and an insulator disposed in at least one flow opening of the injector.

8. The processing chamber of claim 7, wherein the insulator is formed of quartz.

9. The processing chamber of claim 1, wherein the injector comprises a hatch and a seal.

10. A gas assembly, comprising:
an injector comprising one or more flow openings; one or more gas lines fluidly coupled to the one or more flow openings of the injector; and
one or more resistive heaters disposed within at least one of the one or more flow openings;
a hatch coupled the injector, the hatch at least partially supporting the one or more resistive heaters;
a seal disposed about at least one of the one or more resistive heaters; and
one or more electrical lines coupled to the hatch, the one or more electrical lines electrically connected to the one or more resistive heaters.

11. The gas assembly of claim 10, the one or more flow openings comprise an heated flow openings and thermally passive flow openings disposed in an alternating arrangement with respect to each other.

12. The gas assembly of claim 10, further comprising a power source electrically connected to the one or more electrical lines.

13. The gas assembly of claim 10, wherein the one or more resistive heaters comprise a coil, a wire, a rod, or a combination thereof.

14. The gas assembly of claim 10, wherein the one or more resistive heaters comprise silicon carbide, a metallic material, or a ceramic material.

15. The gas assembly of claim 10, wherein the injector comprises one or more cooling channels.

16. The gas assembly of claim 10, wherein the injector comprises an insulator in at least one flow opening of the injector.

17. A method of substrate processing comprising:
applying a power to a heater disposed along a portion of a gas flow path;
flowing one or more process gases along the gas flow path into an injector of a processing chamber;
heating the one or more process gases prior to the one or more process gases flowing out of the injector; and
flowing the one or more process gases into a processing volume of the processing chamber.

18. The method of claim 17, wherein the heater is disposed around one or more gas lines fluidly coupled to the injector, and the one or more process gases are heated by the heater while the one or more process gases flow through the one or more gas lines.

19. The method of claim 17, wherein the heater is disposed within one or more flow openings of the injector, and the one or more process gases are heated by the heater while the one or more process gases flow through the one or more flow openings of the injector.

20. The method of claim 17, wherein the heater comprises a rod electrically coupled to a power source through a hatch disposed in the injector.
